(19) United States
(12) Patent Application Publication
(10) Pub. No.: US 2020/0412326 A1
(43) Pub. Date: Dec. 31, 2020

(54) COMPOSITE SUBSTRATE FOR SURFACE ACOUSTIC WAVE DEVICE AND MANUFACTURING METHOD THEREOF

(71) Applicant: Shin-Etsu Chemical Co., Ltd., Tokyo (JP)

(72) Inventors: Masayuki TANNO, Gunma (JP); Shoji AKIYAMA, Gunma (JP)

(73) Assignee: Shin-Etsu Chemical Co., Ltd., Tokyo (JP)

(21) Appl. No.: 16/909,042

(22) Filed: Jun. 23, 2020

(30) Foreign Application Priority Data
Jun. 26, 2019 (JP) 2019-118379

(51) Int. Cl. H03H 9/02; H03H 9/05; H03H 9/25; H03H 3/08

(52) U.S. Cl. CPC H03H 9/02559; H03H 3/08; H03H 9/25; H03H 9/058

(57) ABSTRACT

A composite substrate for surface acoustic wave devices with improved characteristics is provided. The composite substrate for a surface acoustic wave device according to the present invention is configured to include a piezoelectric single crystal substrate and a supporting substrate. An intervening layer is provided between the piezoelectric single crystal substrate and the supporting substrate, the amount of chemisorbed water in the intervening layer is 1×1020 molecules/cm3 or less. At the bonding interface between the piezoelectric single crystal substrate and the supporting substrate, at least one of the piezoelectric single crystal substrate and the supporting substrate may have an uneven structure. It is preferable that the ratio of the average length RSm of the element in the sectional curve of the uneven structure and the wavelength λ of the surface acoustic wave when used as a surface acoustic wave device is 0.2 or more and 7.0 or less.

### CROSS-REFERENCE TO RELATED APPLICATION

This non-provisional application claims priority under U.S.C. § 119(a) from Japanese Patent Application No. 2019-118379, filed on Jun. 26, 2019, the entire contents of which are incorporated herein by reference.

### BACKGROUND

### Technical Field

The present invention relates to a composite substrate for a surface acoustic wave device in which a piezoelectric single crystal substrate and a supporting substrate are bonded, a method for manufacturing the same, and a surface acoustic wave device using the composite substrate.

### Background Art

In recent years, in the market of mobile communications typified by smartphones, data traffic has been rapidly increased. To cope with this, it is necessary to increase the number of communication bands, and it is indispensable to miniaturize various parts such as surface acoustic wave devices and to achieve high performance of the parts.

Piezoelectric materials such as lithium tantalate (LT) and lithium niobate (LN) are widely used as materials for surface acoustic wave (SAW) devices (e.g., surface acoustic wave filters). Although these materials have a large electromechanical coupling coefficient and the bandwidth of the devices can be broadened, there is a problem that the temperature stability of the materials is low, and so the adaptable frequency is shifted by the temperature change. This is because lithium tantalate or lithium niobate has a very high thermal expansion coefficient.

In order to solve the problem, there has been proposed a composite substrate obtained by bonding a material having a small thermal expansion coefficient to lithium tantalate or lithium niobate and thinning the side of the piezoelectric material to a thickness of several μm to several tens μm. In this composite substrate, the thermal expansion of the piezoelectric material is suppressed by bonding the material having a small thermal expansion coefficient such as sapphire or silicon, and thereby, the temperature characteristics are improved (Non Patent Documents 1 and 2). Further, Patent Document 1 discloses an acoustic wave device having a piezoelectric film. This acoustic wave device includes a supporting substrate, a high acoustic velocity film formed on the supporting substrate and having a higher bulk acoustic velocity than the acoustic velocity propagating through the piezoelectric film, and a low acoustic velocity film stacked on the high acoustic velocity film and having a slower bulk acoustic velocity than the bulk acoustic velocity propagating through the piezoelectric film, the piezoelectric film stacked on the low acoustic velocity film, and an IDT electrode formed on one surface of the piezoelectric film.

Further, Patent Document 2 discloses an acoustic wave device including a supporting substrate, a medium layer stacked on the supporting substrate, a piezoelectric body stacked on the medium layer for propagating a bulk wave, and an IDT electrode formed on one surface of the piezoelectric body. In this device, the medium layer includes a low-speed medium in which the propagation velocity of the bulk wave, which is the main component of an acoustic wave, is slower than the acoustic velocity of the acoustic wave propagating in the piezoelectric body, and a high-speed medium in which the propagation velocity of the bulk wave, which is the main component of the acoustic wave, is a faster than the acoustic velocity of the acoustic wave propagating in the piezoelectric body. The medium layer is formed such that the acoustic velocity of the main vibration mode in the acoustic wave device having the medium layer is VL<the acoustic velocity of the main vibration mode <VH, where the acoustic velocity of the main vibration mode when the medium layer is formed of the high-speed medium is VH and the acoustic velocity of the main vibration mode when the medium layer is formed of the low-speed medium is VL, and the thickness of the medium layer is 1λ or more when the period of the IDT is λ.

Further, Patent Document 3 discloses a composite substrate for a surface acoustic wave device including a piezoelectric single crystal substrate and a supporting substrate. In this device, at the bonding interface between the piezoelectric single crystal substrate and the supporting substrate, at least one of the piezoelectric single crystal substrate and the supporting substrate have an uneven structure, and the ratio of the average length RSm of the element in the sectional curve of the uneven structure and the wavelength λ of the surface acoustic wave when used as a surface acoustic wave device is 0.2 or more and 7.0 or less.

### PRIOR ART REFERENCES

### Patent Documents

Patent Document 1: Japanese Patent No. 5713025
Patent Document 2: Japanese Patent No. 5861789
Patent Document 3: Japanese Patent No. 6250856

### Non Patent Documents

Non Patent Document 1: Temperature Compensation Technology for SAW-Duplexer Used in RF Front End of Smartphone, Dempa Shimbun High Technology, Nov. 8, 2012
Non Patent Document 2: A study on Temperature-Compensated Hybrid Substrates for Surface Acoustic Wave Filters”, 2010 IEEE International Ultrasonic Symposium Proceedings, page 637-640.

### SUMMARY OF THE INVENTION

### Problems to be Solved by the Invention

However, as a result of intensive investigation by the inventor, it has been found that when the surface acoustic wave filter is manufactured using the above-mentioned composite substrate, there is a problem that the intervening layer between the supporting substrate and the piezoelectric substrate swells and the characteristics of the surface acoustic wave filter may change over time. Further, when the above-described composite substrate is used, there is a problem that noise called spurious or ripple occurs within the pass band of the M surface acoustic wave filter or at a higher frequency. This noise occurs due to reflection at the bonding interface between the piezoelectric crystal film and the supporting substrate, and trapping of elastic waves in the intervening layer between the piezoelectric crystal film and the supporting substrate. This noise is not preferable because it deteriorates the frequency characteristics of the surface acoustic wave filter and causes an increased in loss.

### Means for Solving the Problems

To solve the above problems, the composite substrate for a surface acoustic wave device according to the present invention is configured to include a piezoelectric single crystal substrate and a supporting substrate. An intervening layer is provided between the piezoelectric single crystal substrate and the supporting substrate, the amount of chemisorbed water in the intervening layer is 1×10²⁰ molecules/cm³ or less.

In the present invention, at the bonding interface between the piezoelectric single crystal substrate and the supporting substrate, at least one of the piezoelectric single crystal substrate and the supporting substrate may have an uneven structure. It is preferable that the ratio of the average length RSm of the element in the sectional curve of the uneven structure and the wavelength λ of the surface acoustic wave when used as a surface acoustic wave device is 0.2 or more and 7.0 or less.

In the present invention, an acoustic velocity of a slow transversal wave of the intervening layer may be faster than an acoustic velocity of a slow transversal wave of the piezoelectric substrate.

In the present invention, the intervening layer may include SiOx (x=2±0.5). Alternatively, the intervening layer may include a silicon oxynitride film, SiN, amorphous Si, polycrystalline Si, amorphous SiC, Al₂O₃, or ZrO.

In the present invention, the thickness of the intervening layer is preferably not less than 0.2λ and not more than 1λ, where λ is the wavelength of the surface acoustic wave.

In the present invention, the thickness of the piezoelectric single crystal substrate is preferably not less than 1λ and not more than 6λ, where λ is the wavelength of the surface acoustic wave.

In the present invention, the supporting substrate may be any of silicon, glass, quartz glass, alumina, sapphire, silicon carbide, silicon nitride, and crystalline quartz. If the supporting substrate is a silicon substrate having an uneven structure, the uneven structure may be a pyramidal shape.

In the present invention, the piezoelectric single crystal substrate may be a lithium tantalate single crystal substrate or a lithium niobate single crystal substrate. The piezoelectric single crystal substrate is preferably a rotated Y-cut lithium tantalate single crystal substrate whose crystal orientation is rotated 36° Y to 49° Y or rotated 216° Y to 229° Y. The piezoelectric single crystal substrate may be a lithium tantalate single crystal substrate doped with Fe at a concentration of from 25 ppm to 150 ppm.

In the present invention, when the piezoelectric single crystal substrate is a lithium tantalate single crystal substrate, it is preferable that the lattice constant of the X-axis of the tail side of the lithium tantalate single crystal, which is the base material of the lithium tantalate single crystal substrate, is 5.15404 Å to 5.15410 Å at 23° C.

Further, a method of manufacturing a composite substrate for a surface acoustic wave device according to the present invention includes at least a step of providing an uneven structure on the surface of the piezoelectric single crystal substrate and/or the supporting substrate, and a step of providing an intervening layer on the uneven structure. The method for manufacturing further comprises any one of a step of bonding the intervening layer provided on the piezoelectric single crystal substrate and the supporting substrate, a step of bonding the intervening layer provided on the supporting substrate and the piezoelectric single crystal substrate, and a step of bonding the intervening layer provided on the piezoelectric single crystal substrate and the intervening layer provided on the supporting substrate. The amount of chemisorbed water in the intervening layer may be 1×10²⁰ molecules/cm³ or less.

In the present invention, the method of manufacturing may include a step of mirror-finishing the surface of the intervening layer. Further, the intervening layer may be heat-treated at 400° C. or lower.

### BRIEF DESCRIPTION OF THE DRAWINGS

FIG. 1 shows a cross-sectional structure of the composite substrate according to the present embodiment.

FIG. 2 shows a procedure of the method for manufacturing the composite substrate according to the present embodiment.

FIG. 3 shows a relation between the acoustic velocity and the thickness of the LT in the surface acoustic wave filter.

FIG. 4 shows the slowness surface of the 46° rotated Y-cut LT.

FIG. 5 shows an example of the slowness surface when the 46° rotated Y-cut LT is used as the piezoelectric single crystal substrate, and SiO_{1.74}N_{0.26} is used as the intervening layer.

FIG. 6 shows the frequency characteristics of the filter obtained in Example 1.

FIG. 7 shows an example of a chip mounted on a package.

FIG. 8 shows an appearance of a ceramic package after sealing.

FIG. 9 shows a microscopic image of the SiO_{1.74}N_{0.26} film of the LT substrate with SiO_{1.74}N_{0.26} heat-treated at 200° C.

FIG. 10 shows a microscopic image of the SiO_{1.74}N_{0.26} film of the LT substrate with SiO_{1.74}N_{0.26} heat-treated at 400° C. or higher.

FIG. 11 shows the frequency characteristic of the filter obtained in Example 2 in comparison with the frequency characteristic of the filter obtained in Example 1.

### DETAILED DESCRIPTION OF THE EMBODIMENTS

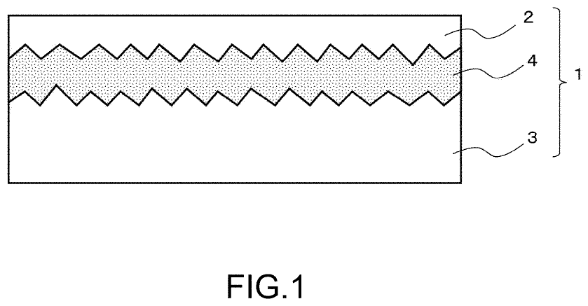

Hereinafter, embodiments of the present invention will be described in detail, but the present invention is not limited thereto. The present invention relates to a composite substrate 1 for surface acoustic wave device configured to include a piezoelectric single crystal substrate 2 and the supporting substrate 3 and a manufacturing method thereof. As shown in FIG. 1, in the composite substrate 1, the intervening layer 4 is provided between the piezoelectric single crystal substrate 2 and the supporting substrate 3.

In the composite substrate 1 of the present embodiment, at least one of the piezoelectric single crystal substrate 2 and the supporting substrate 3 has an uneven structure at the bonding interface between the piezoelectric single crystal substrate 2 and the supporting substrate 3. The uneven structure is formed so that Rsm/λ, which is the ratio of the average length RSm of the element in the sectional curve of the uneven structure and the wavelength λ of the surface acoustic wave when used as a surface acoustic wave device, is 0.2 or more and 7.0 or less. In this way, it is possible to effectively reduce spurious mainly outside the pass band.

Incidentally, the wavelength λ of the surface acoustic wave when used as a surface acoustic wave device is determined by the frequency of the electric signal input to the composite substrate (surface acoustic wave device) and the velocity of the surface wave (leaky wave). The velocity of the surface waves varies depending on the material, and is about 4000 m/s for LiTaO₃. Therefore, when a 2-GHz surface acoustic wave device is manufactured from a composite substrate using LiTaO₃ as a piezoelectric single crystal substrate, the wavelength λ of the surface acoustic wave is about 2 μm. Further, when manufacturing a surface acoustic wave device of 800 MHz from the same composite substrate, the wavelength λ of the surface acoustic wave is about 5 μm.

The arithmetic average roughness Ra in the cross-sectional curve of the uneven structure is not particularly limited, but if Ra is too small, it is considered that the effect of reducing spurious cannot be sufficiently obtained. Therefore, Ra is preferably 100 nm or more. In addition, if Ra is too large, it takes time and cost to provide the intervening layer 4, and it is difficult to uniformly polish the surface, which is not preferable from the viewpoint of manufacturing. Therefore, Ra is preferably 1000 nm or less.

Any type of piezoelectric material may be used for the piezoelectric single crystal substrate 2 as long as it is a composite substrate fora surface acoustic wave device in which spurious is a problem. The thickness of the piezoelectric single crystal substrate 2 may be not less than 1λ and not more than 6λ, where λ is the wavelength of the surface acoustic wave.

As the material of the piezoelectric single crystal substrate 2, for example, a lithium tantalate single crystal substrate or a lithium niobate single crystal substrate having a large electromechanical coupling coefficient may be used. In particular, when a lithium tantalate single crystal substrate is used as the piezoelectric single crystal substrate 2, it is preferable to use a rotated Y-cut lithium tantalate single crystal substrate whose crystal orientation is rotated 36° Y to 49° Y. Alternatively, a rotated Y-cut lithium tantalate single crystal substrate whose crystal orientation is rotated 216° Y to 229° Y with symmetrical crystal structure may be used. Further, as the piezoelectric single crystal substrate, a lithium tantalate single crystal substrate doped with Fe at a concentration of from 25 ppm to 150 ppm may be used.

As the lithium tantalate single crystal substrate or the lithium niobate single crystal substrate, a substrate having a substantially uniform Li concentration in the thickness direction thereof is preferably used. The Li concentration can be a roughly congruent composition or a pseudo stoichiometric composition. A piezoelectric single crystal substrate having a roughly congruent composition is preferable in that it can be relatively easily produced by a known method such as the Czochralski method. Meanwhile, a piezoelectric single crystal substrate having a pseudo stoichiometric composition in which the ratio of Li to Ta or Nb is Li:Ta=50−α:50+α or Li:Nb=50−α:50+α, and a is in a range of −1.0<α<2.5 is preferable because it exhibits a high mechanical coupling coefficient and excellent temperature characteristics.

When a lithium tantalate single crystal substrate is used as the piezoelectric single crystal substrate 2, it is preferable that the lithium tantalate single crystal substrate is based on a lithium tantalate single crystal whose lattice constant of the X-axis of the tail side is 5.15404 Å to 5.15410 Å at 23° C. The Lithium tantalate single crystals with such lattice constants exhibit very small acoustic velocity fluctuations from the seed to the tail, and also exhibit very little acoustic velocity fluctuations in the plane. Therefore, the composite substrate for a surface acoustic wave device including such a lithium tantalate substrate and a supporting substrate has stable acoustic velocity, coupling coefficient, and temperature characteristics within the wafer surface. The surface acoustic wave device using this composite substrate exhibits stable characteristics in the plane.

The supporting substrate may be any of silicon, glass, quartz glass, alumina, sapphire, silicon carbide, silicon nitride, and crystalline quartz. The supporting substrate may be a silicon substrate having an uneven structure. In this case, the uneven structure may be a pyramidal shape.

As described above, the intervening layer 4 is provided between the piezoelectric single crystal substrate 2 and the supporting substrate 3. The thickness of the intervening layer 4 may be not less than 0.2λ and not more than 1λ, where λ is the wavelength of the surface acoustic wave. The intervening layer 4 may be formed of a material having a gas barrier property. The intervening layer 4 may include, for example, a silicon oxynitride film, SiN, amorphous Si, polycrystalline Si, amorphous SiC, Al₂O₃, or ZrO. In addition, the intervening layer may include SiOx (x=2±0.5) or an oxynitride film.

The amount of chemisorbed water in the intervening layer 4 may be 1×10²⁰ molecules/cm³ or less. In this way, it is possible to prevent the characteristics of surface acoustic wave filter from changing with time. Further, when the intervening layer 4 contains a large amount of impurities such as hydrogen and water, volatile components called “outgas” are generated and reliability is lowered. In order to prevent this, it is preferable to form the intervening layer 4 with a purity as high as possible.

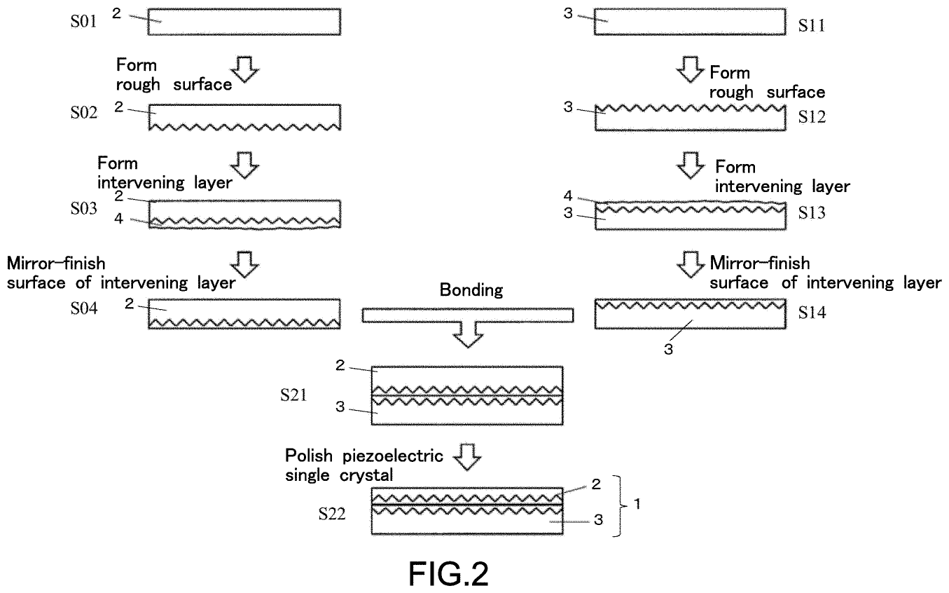

Next, a method of manufacturing the composite substrate 1 according to the present embodiment will be described with reference to FIG. 2.

First, for each of the piezoelectric single crystal substrate 2 and the supporting substrate 3, the process before bonding is performed. To begin with, the piezoelectric single crystal substrate 2 and the support substrate 3 are prepared (S01 and S11 in FIG. 2), and the surfaces thereof are roughened to form an uneven structure (S02 and S12 in FIG. 2). Subsequently, an intervening layer 4 of an inorganic material is deposited on the uneven structure (S03 and S13 in FIG. 2), and then the surface thereof is polished and mirror-finished (S04 and S14 in FIG. 2).

The method of forming the uneven structure on the surface of the piezoelectric single crystal substrate 2 and/or the support substrate 3 is not particularly limited. The surface may be subjected to polishing by selecting the abrasive grains or grindstone so as to have a desired surface roughness, or dry/wet etching may be used.

As a method of depositing an inorganic material such as SiO₂ as the intervening layer 4, for example, a PE-CVD method (plasma-enhanced chemical vapor deposition) or a PVD (physical vapor deposition) method typified by a sputtering method can be used. In addition, silane such as alkoxide silane, silazane such as hexamethyldisilazane, polysilazane such as perhydropolysilazane, silicone oligomer such as silicone oil, or a solution thereof may be applied onto the wafer and cured by heat treatment to deposit the intervening layer 4.

When an inorganic material such as SiO₂ is deposited at a high temperature, warpage or crack occurs when returned to room temperature may be a problem. Therefore, it is preferable to form the intervening layer 4 at a temperature close to room temperature. If the process temperature is set to 70° C. or lower, it is possible to suppress warpage of the substrate to the extent that the substrate can be adsorbed by the vacuum chuck. Specifically, the intervening layer 4 may be formed at a temperature close to room temperature using a room temperature CVD method or magnetron sputtering or the like.

Further, when the intervening layer 4 contains a large amount of impurities such as hydrogen and water, volatile components called “outgas” are generated and reliability is lowered. In order to prevent this, the intervening layer 4 must be formed with a purity as high as possible. For example, the amount of chemisorbed water in the intervening layer may be limited by performing heat treatment, plasma treatment, or UV light irradiation treatment for the intervening layer before bonding.

The piezoelectric single crystal substrate 2 and the supporting substrate 3 whose bonding surfaces (the surface of the deposited intervening layer 4) are mirror-finished are bonded together (S21 in FIG. 2). Then, the piezoelectric single crystal substrate 2 is polished and thinned to a predetermined thickness (S22 in FIG. 2) to obtain the composite substrate 1. The composite substrate 1 thus manufactured has a structure in which both the piezoelectric single crystal substrate 2 and the supporting substrate 3 have an uneven structure.

As described above, the composite substrate 1 configured to include the piezoelectric single crystal substrate 2, the supporting substrate 3, and the intervening layer 4 is preferably configured such that the acoustic velocity of the slow transversal wave of the intervening layer 4 is faster than the acoustic velocity of the slow transversal wave of the piezoelectric single crystal substrate 2. It is possible to prevent the occurrence of ripples mainly in the pass band of the surface acoustic wave filter due to the trapping of the elastic wave in the intervening layer 4 and deterioration of the characteristics of the pass band (that is, loss increase). The mechanism by which such effects are obtained will be described below.

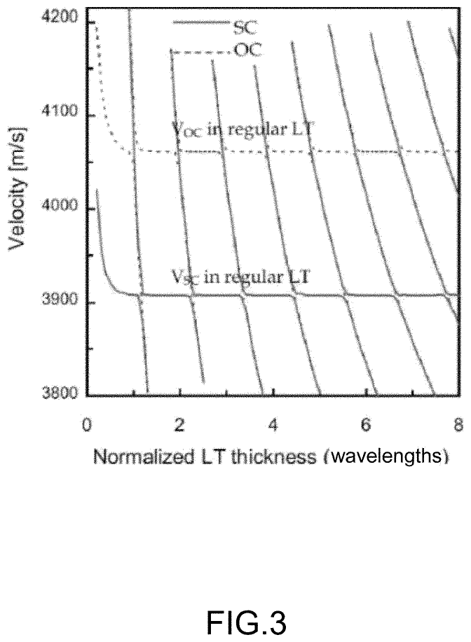

Non-Patent Document 2 shows the relationship between the acoustic velocity (resonance/anti-resonance) and the thickness of the LT normalized by the electrode period λ (FIG. 3) in the surface acoustic wave filter obtained by forming a periodic electrode structure on a composite substrate obtained by bonding the lithium tantalate (LT) and Si. According to this, with respect to the thickness of the LT normalized by the electrode period λ, there is a dispersion relation in which the acoustic velocity is combined with other modes and diverges at some discontinuous LT thicknesses. When a filter is formed using a composite substrate having such a special LT thickness, it is expected that a ripple occurs in the passband, which causes deterioration of characteristics, i.e., an increase in loss.

In the composite substrate 1 of the present embodiment, although the intervening layer 4 is disposed between the piezoelectric single crystal substrate 2 (LT) and the supporting substrate 3, if the velocity of the bulk wave (slow transversal wave) of the intervening layer 4 is slower than the bulk wave (slow transversal wave) of LT, the elastic wave is easily trapped in the intervening layer. In particular, at the LT thickness shown in FIG. 3 where the acoustic velocity is coupled with other modes, elastic wave is easily trapped in the intervening layer. Therefore, if the acoustic velocity of the slow transversal wave of the intervening layer 4 is faster than the acoustic velocity of the slow transversal wave of the piezoelectric single crystal substrate 2 in the composite substrate 1, it is possible to improve the loss in the passband of the surface acoustic wave filter obtained using such a composite substrate 1. Hereinafter, the details will be described.

In the surface acoustic wave filter obtained by forming a periodic electrode structure on the composite substrate, for example, in the composite substrate in which a 46° rotated Y-cut LT and Si are joined and the LT thickness is 1 wavelength or more and the LT thickness excluding the singular point of the dispersion curve, as shown in FIG. 3, the acoustic velocity of the main mode of surface acoustic wave is 4060 m/s (the slowness which is the inverse of the acoustic velocity is 2.46×10⁻³ s/m) when the electrode is electrically open, and is 3910 m/s (the slowness which is the inverse of the acoustic velocity is 2.56×10⁻³ s/m) when the electrode is electrically short-circuited.

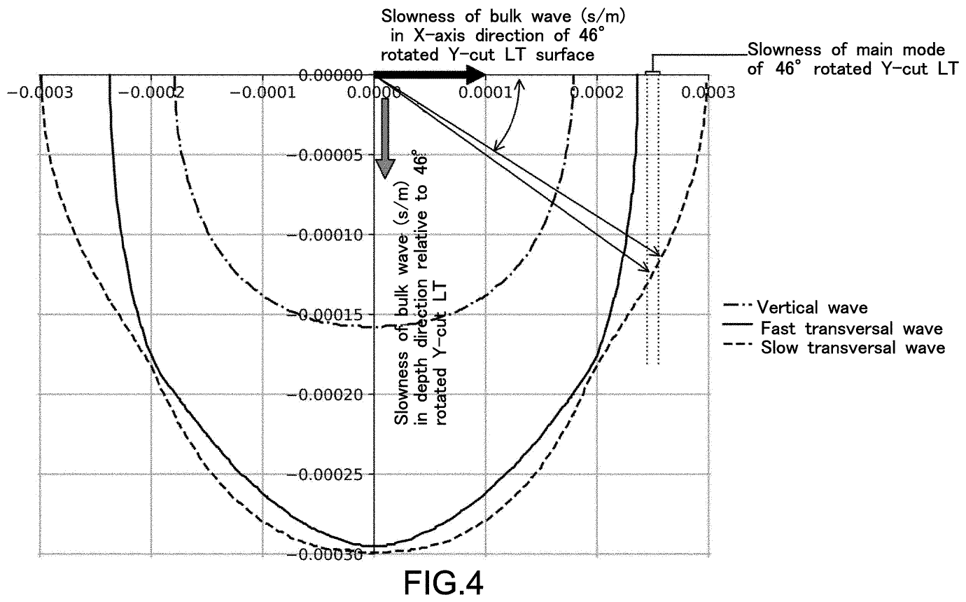

The surface acoustic wave (or leaky wave or SH wave) propagating along the LT surface from the electrodes can be coupled with a specific bulk wave in the LT capable of propagating inside the LT substrate. That is, as shown in the slowness surface (calculated value) of the 46° rotated Y-cut LT shown in FIG. 4, the main mode of the composite substrate structure in which the above-mentioned 46° rotated Y-cut LT and Si are bonded explained above can be coupled with a bulk wave (slow transversal wave) capable of phase matching propagating about 22 degrees in the depth direction from the X-axis.

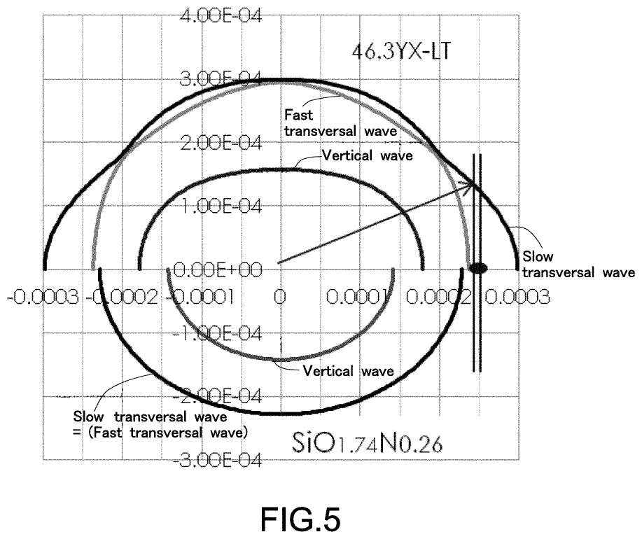

FIG. 5 shows an example of the slowness surface when the 46° rotated Y-cut LT is used as the piezoelectric single crystal substrate, and SiO_{1.74}N_{0.26} is used as the intervening layer. When SiO_{1.74}N_{0.26} is used as the intervening layer, the acoustic velocity of the slow transversal wave of the intervening layer can be made faster than the acoustic velocity of the slow transversal wave of the piezoelectric single crystal substrate.

In a situation where the acoustic velocity of the slow transversal wave of the intervening layer is faster than the acoustic velocity of the slow transversal wave of the piezoelectric single crystal substrate as shown in FIG. 5, the slow transversal wave emitted in the direction of about 22° from the X-axis of the 46° rotated Y-cut LT is totally reflected by the intervening layer even when reaching the intervening layer. Therefore, the bulk wave leaking inward from the surface acoustic wave (or leaky wave or SH wave) propagating along the LT surface from the electrodes is totally reflected by the intervening layer and cannot stay in the intervening layer.

At the singular point where the dispersion curve diverges with respect to the LT thickness shown in FIG. 3, the range of the acoustic velocity at which propagation is possible expands to 3800 to 4200 m/s. If this is expressed by the slowness, the slowness is approximately 2.4×10⁻³ to 2.6×10⁻³ (s/m). Therefore, the bulk wave leaking inward from the surface acoustic wave (or leaky wave or SH wave) propagating along the LT surface from the electrodes can be coupled with a slow transversal wave or a fast transversal wave. However, in a situation illustrated in FIG. 5, the slowness of the slow transversal wave (=fast transversal wave) of the intervening layer is 2.3×10⁻³ (s/m), and the bulk wave due to the main mode from the LT is totally reflected in the intervening layer of the present application.

Furthermore, when the piezoelectric single crystal substrate has an uneven structure at the boundary with the intervening layer, the bulk wave in the direction of approximately 22° due to the main mode from the LT is scattered by the uneven structure and the component returning to the electrode can be drastically reduced.

Therefore, a surface acoustic wave device (filter) using the composite substrate having a structure in which the acoustic velocity of the slow transversal wave of the intervening layer is faster than the acoustic velocity of the slow transversal wave of the piezoelectric substrate is highly reliable and spurious that remains in the intervening layer does not occur much depending on the LT thickness. Accordingly, deterioration of characteristics such as ripple and loss in the pass band of the filter can be prevented.

### EXAMPLES

### Example 1

In Example 1, a 46° rotated Y-cut LT substrate having an uneven structure in which the arithmetic mean roughness Ra was 1500 nm±30%, the mean length of the element in the cross-sectional curve of the uneven structure RSm was 3 μm±10%, and the maximum height Rz was 2.0 μm±10% was prepared. Here, the uneven structure of the LT substrate was formed by polishing using free abrasive grains.

Next, SiO₂ was deposited on the surface of the LT substrate having the uneven structure at 35° C. for about 8 μm by plasma-enhanced CVD, and then the LT substrate with SiO₂ was heated at 200° C. to 600° C. for 48 hours. After the heat treatment, the surface of the LT substrate with SiO₂ on which SiO₂ was deposited was polished to be mirror-finished so that the average thickness of SiO₂ was about 2 μm. Then, both of mirror surface of SiO₂ and mirror surface of the Si substrate serving as the supporting substrate were subjected to plasma-activation, and the LT substrate and the supporting substrate were bonded. Further, the LT substrate was polished and thinned to 18 μm, thereby manufacturing a 6-inch composite substrate.

Further, in order to confirm the effect of the heat treatment, the LT substrate with SiO₂ that had not been subjected to heat treatment was prepared. The surface on which SiO₂ is deposited of the LT substrate with SiO₂ was polished to be mirror-finished so that the average thickness of SiO₂ was about 3 μm. Then, both of mirror surface of SiO₂ and mirror surface of the Si substrate serving as the supporting substrate were subjected to plasma-activation, and the LT substrate and the supporting substrate were bonded. Further, the LT substrate was polished and thinned to 18 μm, thereby manufacturing a 6-inch composite substrate.

In the Example 1 described above, an amount of the chemisorbed water in SiO₂ film of the LT substrate with SiO₂ was determined by a mass spectrometer. The Young's modulus and density of each sample were measured by the nanoindentation method and the X-ray reflectivity (Xrr) method, respectively. Table 1 shows the calculated acoustic velocity of the slow transversal wave of SiO₂ film obtained from the results of Example 1 and Young's modulus and density described above.

TABLE 1

| | Heat treatment temperature (° C.) | | | | | No Heat |
|---|---|---|---|---|---|---|
| | 200 | 300 | 400 | 500 | 600 | treatment |
| Amount of chemisorbed water in | 8 × 10¹⁹ | 3 × 10¹⁹ | 2 × 10¹⁹ | 5 × 10¹⁸ | 1 × 10¹⁸ | 5 × 10²⁰ |
| SiO₂ film of LT substrate with | | | | | | |
| SiO₂ (molecules/cm³) | | | | | | |
| SiO₂ film Young modulus | 62 | 63 | 65 | 68 | 70 | 52 |
| SiO₂ film density (kg/m³) | 2180 | 2185 | 2190 | 2200 | 2200 | 2150 |
| SiO₂ film slow transversal wave | 3710 | 3730 | 3745 | 3755 | 3760 | 3600 |
| acoustic velocity (m/s) | | | | | | |
| Changes in frequency | No change | No change | No change | No change | No change | Insertion |
| characteristics over time | | | | | | loss |
| due to heat cycles | | | | | | deteriorated |

Next, on the surface of the LT substrate of the manufactured 6-inch composite substrate (both those with and without heat treatment on the LT substrate with SiO₂), an Al film having a thickness of 0.4 μm by vapor deposition, and then electrodes were formed by photolithography to form a four-stage ladder filter for a wavelength of about 5 μm comprising two stages of parallel resonators and five stages of series resonators. At this time, a g-line stepper was used for photolithography exposure, and a mixed gas of Cl₂, BCl₃, N₂, and CF₄ was used for Al etching.

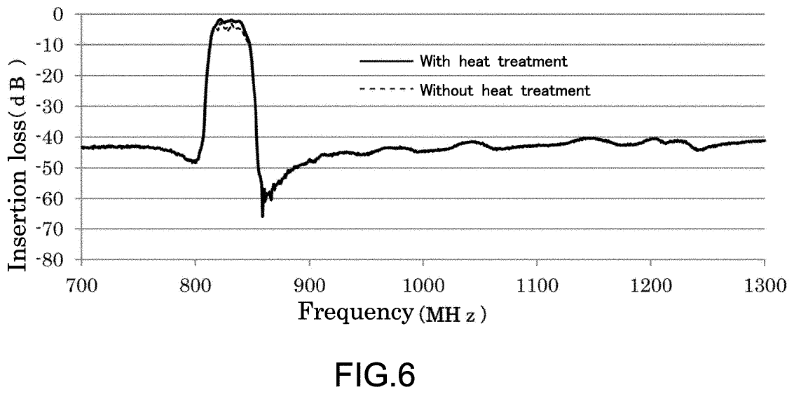

Next, when the frequency characteristics of the filter portion formed on the composite substrate prepared with the heat treatment was measured with an RF probe, the frequency characteristic shown by a solid line in FIG. 6 was obtained. As shown in FIG. 6, there is no noticeable spurious response outside the passband of the filter.

When the frequency characteristics of the filter portion formed on the composite substrate prepared without the heat treatment was measured with the RF probe, the same frequency characteristics as the filter using the composite substrate subjected to the heat treatment was obtained.

In this embodiment, since the wavelength λ of the surface acoustic wave is 5 μm and the RSm is 3 μm, the value of RSm/λ is 0.6.

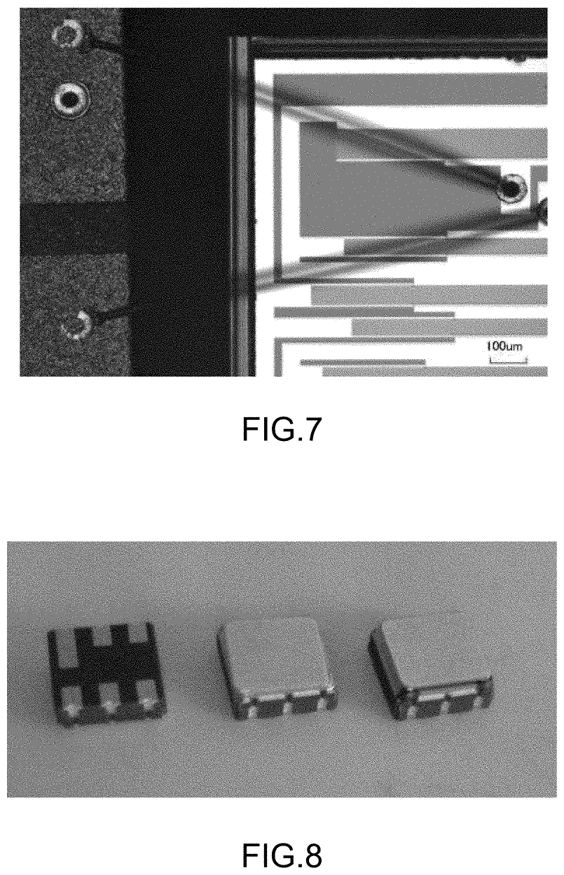

Next, a large number of 1.5 mm-square chips with filter circuit were cut out from 6-inch composite substrates (both those with and without heat treatment on the LT substrate with SiO₂), mounted on ceramic packages, and wired by wire bonding. FIG. 7 shows an example of a chip mounted on a package. The package was covered with a lid and hermetically sealed. FIG. 8 shows an appearance of the ceramic package after sealing.

When the characteristics of the hermetically sealed filter were evaluated, the same frequency characteristics as those shown by the solid line in FIG. 6 were obtained for both those using the composite substrate with the heat treatment and the those using the composite substrate without the heat treatment.

Next, the hermetically sealed surface acoustic wave filters were passed through a reflow furnace at 265° C. six times, and then a heat cycle of −40° C. to 125° C. was performed 1000 times, and further left for 1000 hours in an environment of 125° C. and a humidity of 85% at 2 atm.

Thereafter, the characteristics of the hermetically sealed surface acoustic wave filter was evaluated. For those using the composite substrate subjected to heat treatment, even after passing through the heat cycles, the same frequency characteristics as shown by the solid line in FIG. 6 were obtained. The evaluation results are shown in Table 1. The number of filters evaluated under each condition was 11.

On the other hand, for those using a composite substrate prepared without heat treatment, the same frequency characteristics as shown by the broken line in FIG. 6 were obtained. Initially after mounting, the frequency characteristics were same as those of the filter using the composite substrate manufactured with heat treatment, but after the heat cycles, the insertion loss deteriorated by about 2 dB.

### Example 2

In Example 2, a 46° rotated Y-cut LT substrate having an uneven structure in which the arithmetic mean roughness Ra was 1500 nm±30%, the mean length of the element in the cross-sectional curve of the uneven structure RSm was 3 μm±10%, and the maximum height Rz was 2.0 μm±10% was prepared. Here, the uneven structure of the LT substrate was formed by polishing using free abrasive grains.

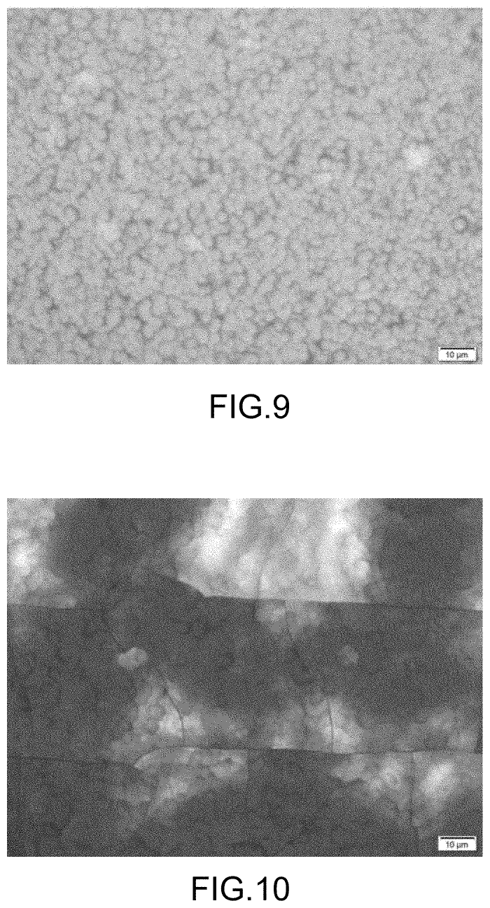

Next, SiO_{1.74}N_{0.26} was deposited on the surface of the LT substrate having the uneven structure at 35° C. for about 8 nm by plasma-enhanced CVD. Then the LT substrate with SiO_{1.74}N_{0.26} was heated at a temperature of room temperature to 600° C. for 48 hours. FIG. 9 shows a microscopic image of the SiO_{1.74}N_{0.26} film of the LT substrate with SiO_{1.74}N_{0.26} heat-treated at 200° C. FIG. 10 shows a microscopic image of the SiO_{1.74}N_{0.26} film of the LT substrate with SiO_{1.74}N_{0.26} heat-treated at 400° C. or higher. It can be seen that cracks occurred by heat treatment at 400° C. or higher.

For the sample which was not cracked by the heating process, the surface of LT-substrate with SiO_{1.74}N_{0.26} where the SiO_{1.74}N_{0.26} film was deposited was polished to be mirror-finished so that the average thickness of the SiO_{1.74}N_{0.26} film was about 3 nm. Then, both of mirror surface of the SiO_{1.74}N_{0.26} film and mirror surface of the Si substrate serving as the supporting substrate were subjected to plasma surface activation, and the LT substrate and the supporting substrate were bonded. Then, the LT substrate was polished to reduce the thickness of LT from 6 μm to 18 μm in steps of 1 μm, thereby a plurality of 6-inch composite substrates were manufactured.

An amount of the chemisorbed water in SiO_{1.74}N_{0.26} film of the LT substrate with SiO_{1.74}N_{0.26} was determined by a mass spectrometer. The Young's modulus and density of each sample were measured by the nanoindentation method and the X-ray reflectivity (Xrr) method, respectively. Table 2 shows the calculated acoustic velocity of the slow transversal wave of SiO_{1.74}N_{0.26} film obtained from the results of Example 2 and Young's modulus and density described above.

TABLE 2

| | No Heat | Heat treatment temperature (° C.) | | | | |
|---|---|---|---|---|---|---|
| | treatment | 200 | 300 | 400 | 500 | 600 |
| Amount of chemisorbed water in | 1 × 10¹⁸ | 1 × 10¹⁸ | 7 × 10¹⁷ | 6 × 10¹⁷ | 5 × 10¹⁷ | 6 × 10¹⁷ |
| SiO_{1.74} No. 26 film (molecules/cm³) | | | | | | |
| Cracking of SiO_{1.74} No. 26 film | None | None | None | Cracking | Cracking | Cracking |
| after heating | | | | | | |
| SiO_{1.74} No. 26 film Young modulus | 98 | 98 | 99 | 99 | 100 | 100 |
| SiO_{1.74} No. 26 film density (kg/m³) | 2280 | 2280 | 2280 | 2281 | 2281 | 2281 |
| SiO_{1.74} No. 26 film slow transversal | 4380 | 4380 | 4380 | 4380 | 4381 | 4381 |
| wave acoustic velocity (m/s) | | | | | | |
| Changes in frequency | No change | No change | No change | — | — | — |
| characteristics over time | | | | | | |
| due to heat cycles | | | | | | |

Next, on the surface of the LT substrate of the manufactured 6-inch composite substrate, an Al film having a thickness of 0.4 μm by vapor deposition, and then electrodes were formed by photolithography to form a four-stage ladder filter for a wavelength of about 5 μm comprising two stages of parallel resonators and five stages of series resonators. At this time, a g-line stepper was used for photolithography exposure, and a mixed gas of Cl₂, BCl₃, N₂, and CF₄ was used for Al etching.

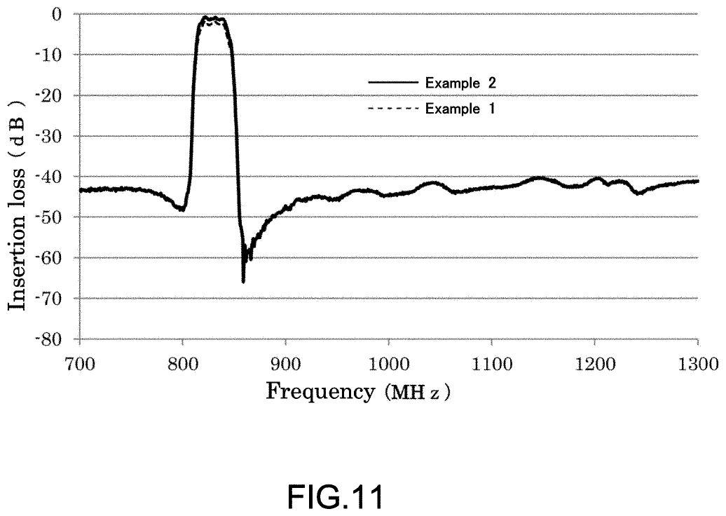

Next, when the characteristics of the filter portion of the wafer formed with patterning was measured with the RF probe, the frequency characteristics shown by a solid line in FIG. 11 for each LT thickness of the wafer was obtained.

In order to confirm the effect of heat treatment, electrode patterns of ladder filters were also formed on the surface of the LT substrate of 6-inch composite substrates with LT thicknesses of 6-18 μm manufactured without heat treatment. When the frequency characteristics of the thus obtained filter was measured with the RF probe, the same frequency characteristics as the filter using the composite substrate subjected to the heat treatment was obtained.

In Example 2, since the wavelength λ of the surface acoustic wave is 5 μm and the RSm is 3 μm, the value of RSm/λ is 0.6.

As shown in FIG. 11, it can be seen that there is no noticeable spurious response outside the passband of the filter. In addition, it can be seen that the insertion loss was improved as compared with the filter in Example 1 shown by the broken line in FIG. 11.

Next, a large number of 1.5 mm-square chips with filter circuit were cut out from 6-inch composite substrates (both those with and without heat treatment), mounted on ceramic packages, and wired by wire bonding. The chip mounted on the package is the same as that shown in FIG. 7. The package was covered with a lid and hermetically sealed. The appearance of the ceramic package after sealing is the same as that of FIG. 8.

The characteristics of the hermetically sealed surface acoustic wave filter made of the composite substrate of the present application was evaluated. In all cases, the frequency characteristics were similar to those shown by the solid line in FIG. 11. However, with respect to the sample heated at 400° C. or higher, the characteristics of the device were not evaluated because it was impossible to manufacture a 6-inch composite substrate because bonding of the substrates was impossible.

Next, the hermetically sealed surface acoustic wave filters were passed through a reflow furnace at 265° C. six times, and then a heat cycle of −40° C. to 125° C. was performed 1000 times, and further left for 1000 hours in an environment of 125° C. and a humidity of 85% at 2 atm.

Thereafter, the characteristics of the surface acoustic wave filter was evaluated. Even after passing through the heat cycles, the same frequency characteristics as shown by the solid line in FIG. 11 were obtained. The evaluation results are shown in Table 2. The number of filters evaluated under each condition was 11.

As described above, by using the composite substrate for a surface acoustic wave device of the present invention, a surface acoustic wave device having preferable characteristics can be obtained.

1. A composite substrate for a surface acoustic wave device comprising a piezoelectric single crystal substrate and a supporting substrate, wherein an intervening layer is provided between the piezoelectric single crystal substrate and the supporting substrate, and the amount of chemisorbed water in the intervening layer is 1×1020 molecules/cm³ or less.

2. The composite substrate for the surface acoustic wave device according to claim 1, wherein at least one of the piezoelectric single crystal substrate and the supporting substrate has an uneven structure at the bonding interface between the piezoelectric single crystal substrate and the supporting substrate, and the ratio of the average length RSm of the element in the sectional curve of the uneven structure and the wavelength λ of the surface acoustic wave when used as the surface acoustic wave device is 0.2 or more and 7.0 or less.

3. The composite substrate for the surface acoustic wave device according to claim 1, wherein an acoustic velocity of a slow transversal wave of the intervening layer is faster than an acoustic velocity of a slow transversal wave of the piezoelectric substrate.

4. The composite substrate for the surface acoustic wave device according to claim 1, wherein the composite substrate includes SiOₓ (x=2±0.5) as the intervening layer.

5. The composite substrate for the surface acoustic wave device according to claim 1, wherein the composite substrate includes any one of a silicon oxynitride film, SiN, amorphous Si, polycrystalline Si, amorphous SiC, Al₂O₃, and ZrO as the intervening layer.

6. The composite substrate for the surface acoustic wave device according to claim 1, wherein the thickness of the intervening layer is not less than 0.2λ and not more than 1λ, where λ is the wavelength of the surface acoustic wave.

7. The composite substrate for the surface acoustic wave device according to claim 6, wherein the thickness of the piezoelectric single crystal substrate is not less than 1λ, and not more than 6λ.

8. The composite substrate for the surface acoustic wave device according to claim 1, wherein the supporting substrate is any of silicon, glass, quartz glass, alumina, sapphire, silicon carbide, silicon nitride, and crystalline quartz.

9. The composite substrate for the surface acoustic wave device according to claim 1, wherein the supporting substrate is a silicon substrate having an uneven structure, and the uneven structure is a pyramidal shape.

10. The composite substrate for the surface acoustic wave device according to claim 1, wherein the piezoelectric single crystal substrate is a lithium tantalate single crystal substrate or a lithium niobate single crystal substrate.

11. The composite substrate for the surface acoustic wave device according to claim 1, wherein the piezoelectric single crystal substrate is a rotated Y-cut lithium tantalate single crystal substrate whose crystal orientation is rotated 36° Y to 49° Y or rotated 216° Y to 229° Y.

12. The composite substrate for the surface acoustic wave device according to claim 9, wherein the piezoelectric single crystal substrate is a lithium tantalate single crystal substrate doped with Fe at a concentration of from 25 ppm to 150 ppm.

13. The composite substrate for the surface acoustic wave device according to claim 1, wherein the piezoelectric single crystal substrate is a lithium tantalate single crystal substrate, and the lithium tantalate single crystal substrate is based on a lithium tantalate single crystal whose lattice constant of the X-axis of the tail side is 5.15404 Å to 5.15410 Å at 23° C.

14. A method of manufacturing a composite substrate for a surface acoustic wave device comprising at least:
providing an uneven structure on the surface of a piezoelectric single crystal substrate and/or a supporting substrate; and
providing an intervening layer on the uneven structure, wherein the method further comprises one of:
i) bonding the intervening layer provided on the piezoelectric single crystal substrate and the supporting substrate, ii) bonding the intervening layer provided on the supporting substrate and the piezoelectric single crystal substrate, and iii) bonding the intervening layer provided on the piezoelectric single crystal substrate and the intervening layer provided on the supporting substrate, and
wherein the amount of chemisorbed water in the intervening layer is 1×1020 molecules/cm³ or less.

15. The method of manufacturing the composite substrate for the surface acoustic wave device according to claim 14, further comprises mirror-finishing the surface of the intervening layer.

16. The method of manufacturing the composite substrate for the surface acoustic wave device according to claim 14, wherein the intervening layer is heat-treated at 400° C. or less.
